(19) United States
(12) Patent Application Publication
(10) Pub. No.: US 2025/0185245 A1
(43) Pub. Date: Jun. 5, 2025

(54) MEMORY DEVICE AND METHOD OF MANUFACTURING THE MEMORY DEVICE

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 18/627,594

(22) Filed: Apr. 5, 2024

(30) Foreign Application Priority Data
Dec. 4, 2023 (KR) 10-2023-0173533

(51) Int. Cl. H10B 43/27; H10B 43/35

(52) U.S. Cl. CPC H10B 43/27; H10B 43/35

(57) ABSTRACT

Provided herein is a memory device and a method of manufacturing the same. The memory device including a stacked body, a channel layer penetrating the stacked body, a tunnel isolation layer enclosing an outer side surface of the channel layer, a capping layer extending from the channel layer and protruding upward from the stacked body, a spacer enclosing an outer side surface of the capping layer on the stacked body, and a liner layer extending along a top surface of the stacked body and an outer side surface of the spacer. In an embodiment, the tunnel isolation layer having a first thickness, and the spacer may have a second thickness greater than the first thickness. In an embodiment, the spacer having a first height, and the liner layer having a second height lower than the first height.

### CROSS-REFERENCE TO RELATED APPLICATION

The present application claims priority under 35 U.S.C. § 119(a) to Korean patent application number 10-2023-0173533 filed on Dec. 4, 2023, in the Korean Intellectual Property Office, the entire contents of which application is incorporated herein by reference.

### BACKGROUND

### 1. Technical Field

Various embodiments of the present disclosure generally relate to a memory device and a method of manufacturing the memory device, and more particularly, to a memory device including a memory block having a three-dimensional (3D) structure and a method of manufacturing the memory device having the three-dimensional (3D) structure.

### 2. Related Art

Memory devices may include nonvolatile memory devices in which stored data is retained even when power supply is interrupted. The nonvolatile memory devices may be classified into a two-dimensional (2D) structure and a three-dimensional (3D) structure according to the structure in which memory cells are arranged. The memory cells of a nonvolatile memory device having a 2D structure may be arranged in a single layer on a substrate, and the memory cells of a nonvolatile memory device having a 3D structure may be vertically stacked on the substrate. Because the degree of integration of the nonvolatile memory device having a 3D structure is higher than that of the nonvolatile memory device having a 2D structure, the number of electronic devices using the nonvolatile memory device having a 3D structure has recently increased.

### SUMMARY

An embodiment of the present disclosure may provide for a memory device. The memory device may include a stacked body, a channel layer penetrating the stacked body, a tunnel isolation layer enclosing an outer side surface of the channel layer and having a first thickness, a capping layer extending from the channel layer and protruding upward from the stacked body, a spacer enclosing an outer side surface of the capping layer on the stacked body and having a second thickness greater than the first thickness, and a liner layer extending along a top surface of the stacked body and an outer side surface of the spacer.

An embodiment of the present disclosure may provide for a method of manufacturing a memory device. The method may include forming a preliminary channel layer penetrating a stacked body, and a tunnel isolation layer enclosing an outer side surface of the preliminary channel layer and the tunnel isolation layer having a first thickness, forming a preliminary capping layer contacting a top of the preliminary channel layer, exposing a portion of the preliminary channel layer by removing an upper portion of the stacked body, forming a spacer having a second thickness greater than the first thickness by oxidizing the exposed preliminary channel layer and the preliminary capping layer, and forming a liner layer extending along a top surface of the stacked body and the spacer.

An embodiment of the present disclosure may provide for a memory device. The memory device may include a stacked body, a channel layer penetrating the stacked body, a capping layer extending from the channel layer and protruding upward from the stacked body, a spacer enclosing an outer side surface of the capping layer on the stacked body and having a first height, and a liner layer extending along a top surface of the stacked body and an outer side surface of the spacer, and having a second height lower than the first height, wherein the liner layer extends along a portion of the outer side surface of the spacer to externally expose a portion of the outer side surface of the spacer.

An embodiment of the present disclosure may provide for a method of manufacturing a memory device. The method may include forming a preliminary channel layer penetrating a stacked body, forming a preliminary capping layer contacting a top of the preliminary channel layer, exposing a portion of the preliminary channel layer by removing an upper portion of the stacked body, forming a spacer having a first height by oxidizing an exposed preliminary channel layer and the preliminary capping layer, and forming a liner layer extending along a top surface of the stacked body and at least a portion of the spacer, the liner layer having a second height lower than the first height.

### BRIEF DESCRIPTION OF THE DRAWINGS

FIG. 1 is a diagram illustrating a memory device according to an embodiment of the present disclosure.

FIG. 2 is a circuit diagram for explaining a connection configuration of a memory block according to an embodiment of the present disclosure.

FIG. 3 is a view illustrating the structure of a memory device according to an embodiment of the present disclosure.

FIGS. 4A to 4J are views illustrating a method of manufacturing a memory device according to an embodiment of the present disclosure.

FIG. 5 is a diagram illustrating an example of a source line included in a memory device according to an embodiment of the present disclosure.

FIG. 6 is a diagram illustrating a memory card system to which a memory device according to the present disclosure is applied.

FIG. 7 is a diagram illustrating a solid state drive (SSD) system to which a memory device according to the present disclosure is applied.

### DETAILED DESCRIPTION

Specific structural or functional descriptions in the embodiments according to the concept of the present disclosure introduced in this specification or application are only for description of the embodiments according to the concept of the present disclosure. The embodiments according to the concept of the present disclosure may be practiced in various forms, and should not be construed as being limited to the embodiments described in the specification or application.

Hereinafter, various embodiments of the present disclosure will be described in detail with reference to the accompanying drawings in which embodiments of the present disclosure are shown so that those skilled in the art to which the present disclosure pertains can practice the technical spirit of the present disclosure.

Various embodiments of the present disclosure are directed to a memory device and a method of manufacturing the memory device, which can improve the structure of a select transistor.

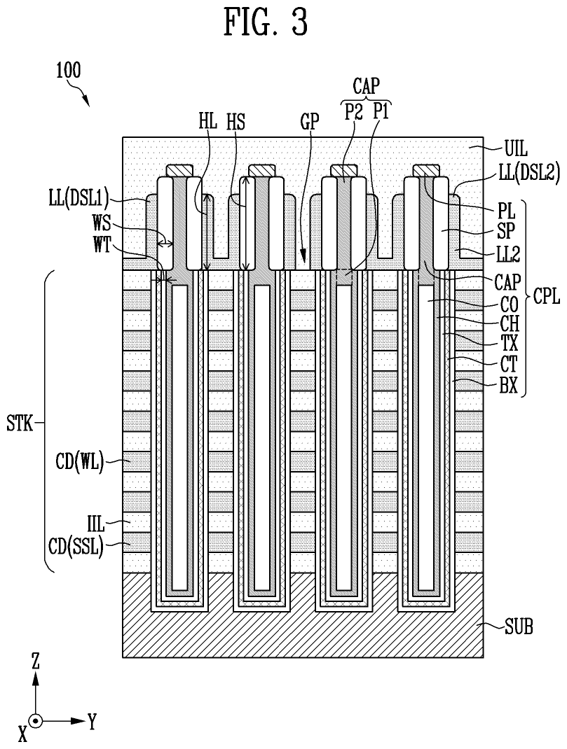

Spatially relative terms, such as “beneath,” “below,” “lower,” “above,” “upper”, “upward”, “under”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout. It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure. For example, in an embodiment, the Z direction may be a first direction, the Y direction may be a second direction, and the X direction may be a third direction as shown in FIG. 3.

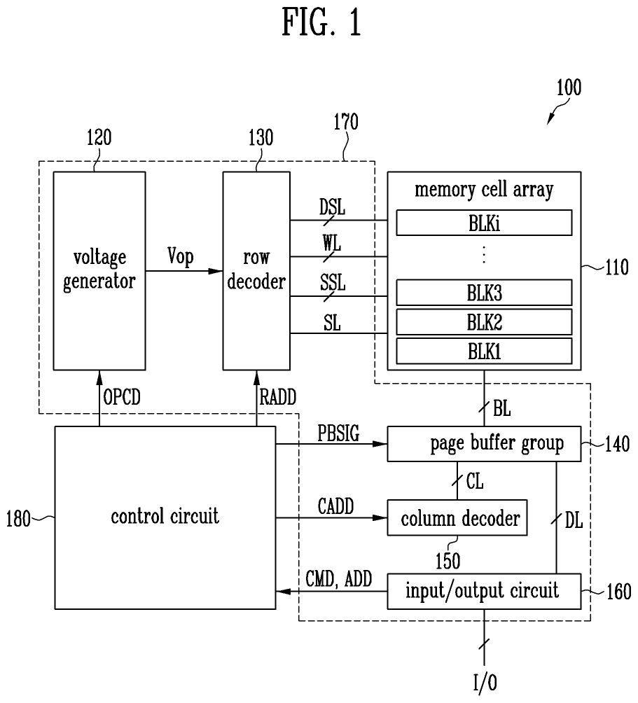

FIG. 1 is a diagram illustrating a memory device according to an embodiment of the present disclosure.

Referring to FIG. 1, a memory device 100 may include a memory cell array 110, a peripheral circuit 170, and a control circuit 180.

The memory cell array 110 may include first to i-th memory blocks BLK1 to BLKi. Each of the first to i-th memory blocks BLK1 to BLKi may include a plurality of memory cells that are capable of storing data. Drain select lines DSL, word lines WL, source select lines SSL, and a source line SL may be coupled to each of the first to i-th memory blocks BLK1 to BLKi, and bit lines BL may be coupled in common to the first to i-th memory blocks BLK1 to BLKi.

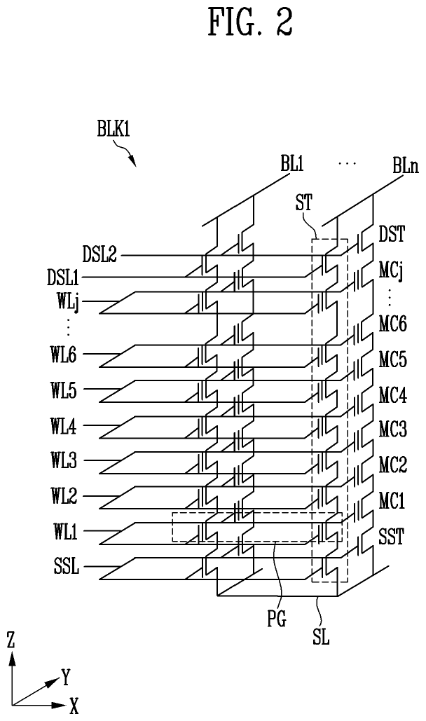

Each of the first to i-th memory blocks BLK1 to BLKi may be formed to have a three-dimensional (3D) structure. Each memory block having a 3D structure may include memory cells stacked on a substrate in a vertical direction (i.e., Z direction). Components included in each of the first to i-th memory blocks BLK1 to BLKi will be described later with reference to FIG. 2.

According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 170 may perform a program operation of storing data in the memory cell array 110, a read operation of outputting data stored in the memory cell array 110, and an erase operation of erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop that are used for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a memory block selected through the row decoder 130.

The program voltages may be voltages that are applied to a selected word line among the word lines WL during a program operation, and may be used to increase the threshold voltages of memory cells coupled to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off the drain select transistors or source select transistors. For example, the turn-off voltage may be set to 0 V. The precharge voltages may be voltages higher than 0 V, and may be applied to the bit lines during a read operation. The verify voltages may be used for a verify operation of determining whether the threshold voltages of selected memory cells have increased to a target level. The verify voltages may be set to various levels according to the target level, and may be applied to a selected word line.

The read voltages may be applied to the selected word line during a read operation performed on the selected memory cells. For example, the read voltages may be set to various levels according to the program scheme for the selected memory cells. The pass voltages may be voltages that are applied to unselected word lines among the word lines WL during a program or read operation, and may be used to turn on memory cells coupled to the unselected word lines. The erase voltages may be used during an erase operation of erasing the memory cells included in the selected memory block, and may be applied to the source line SL.

The row decoder 130 may transfer the operating voltages Vop to the drain select lines DSL, the word lines WL, the source select lines SSL, and the source line SL, which are coupled to a memory block selected according to the row address RADD. For example, the row decoder 130 may be coupled to the voltage generator 120 through global lines, and may be coupled to the first to i-th memory blocks BLK1 to BLKi through the drain select lines DSL, the word lines WL, the source select lines SSL, and the source line SL.

The page buffer group 140 may include page buffers (not illustrated) coupled to the first to i-th memory blocks BLK1 to BLKi, respectively. The page buffers (not illustrated) may be coupled to the first to i-th memory blocks BLK1 to BLKi through the bit lines BL. During a read operation the page buffers (not illustrated) may sense the currents or voltages of bit lines varying with the threshold voltages of the selected memory cells in response to page buffer control signals PBSIG, and may store, for a limited duration, the sensed data.

The column decoder 150 may be configured such that data is transferred between the page buffer group 140 and the input/output circuit 160 in response to a column address CADD. For example, the column decoder 150 may be coupled to the page buffer group 140 through column lines CL, and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 180, and may transmit the data, received from the external controller through the input/output lines I/O, to the page buffer group 140. Alternatively, the input/output circuit 160 may output data, received from the page buffer group 140, to the external controller through the input/output lines I/O.

The control circuit 180 may output at least one of the operation code OPCD, the row address RADD, the page buffer control signals PBSIG, or the column address CADD in response to the command CMD and the address ADD. For example, when the command CMD input to the control circuit 180 is a command corresponding to a program operation, the control circuit 180 may control the peripheral circuit 170 so that a program operation is performed on a memory block selected by the address ADD. When the command CMD input to the control circuit 180 is a command corresponding to a read operation, the control circuit 180 may control the peripheral circuit 170 so that a read operation is performed on a memory block selected by the address and read data is output. When the command CMD input to the control circuit 180 is a command corresponding to an erase operation, the control circuit 180 may control the peripheral circuit 170 so that an erase operation is performed on a selected memory block.

FIG. 2 is a circuit diagram for explaining a connection configuration of a memory block according to an embodiment of the present disclosure.

Referring to FIG. 2, each of memory blocks (e.g., a first memory block BLK1) may include strings ST coupled between first to n-th bit lines BL1 to BLn and a source line SL. Because the first to n-th bit lines BL1 to BLn individually extend along a Y direction and are arranged to be spaced apart from each other along an X direction, the strings ST may also be arranged to be spaced apart from each other along the X and Y directions. For example, strings ST may be arranged between the first bit line BL1 and the source line SL, and strings ST may be arranged between the second bit line BL2 and the source line SL. In this way, strings ST may be arranged between the n-th bit line BLn and the source line SL. Each of the strings ST may extend along a Z direction.

Any one string ST, among the strings ST coupled to the n-th bit line BLn, will be described in detail below by way of example. That is, the string ST may include a source select transistor SST, first to i-th memory cells MC1 to MCj, and a drain select transistor DST. Because the first memory block BLK1 illustrated in FIG. 2 schematically explains the structure of the memory block, the numbers of source select transistors SST, first to j-th memory cells MC1 to MCj, and drain select transistors DST included in each of the strings ST may vary depending on the memory device.

Gates of source select transistors SST included in different strings ST may be coupled to a source select line SSL. Gates of the first to j-th memory cells MC1 to MCj included in different strings ST may be coupled to first to j-th word lines WL1 to WLj, respectively. Gates of drain select transistors DST included in different strings ST may be coupled to a first drain select line DSL1 or a second drain select line DSL2.

Memory cells formed on the same layer, among the first to j-th memory cells MC1 to MCj, may be coupled to the same word line. For example, the first memory cells MC1 included in different strings ST may be coupled in common to the first word line WL1, and j-th memory cells MCj included in different strings ST may be coupled in common to the j-th word line WLj. A group of memory cells included in different strings ST and coupled to the same word line may be a page (PG). Program and read operations may be performed on a page (PG) basis.

Drain select transistors DST arranged in the Y direction may be coupled to the first and second drain select lines DSL1 and DSL2 separated from each other. In detail, the drain select transistors DST arranged along the X direction may be coupled to the same drain select line. Further, drain select transistors DST arranged along the Y direction may be coupled to the first and second drain select lines DSL1 and DSL2, respectively, separated from each other. Since the first and second drain select lines DSL1 and DSL2 are separated from each other, different voltages may be applied to the first and second drain select lines DSL1 and DSL2.

FIG. 3 is a view illustrating the structure of a memory device according to an embodiment of the present disclosure.

FIG. 3 illustrates a portion of the memory device 100 illustrated in FIG. 1, for example, a portion of a first memory block BLK1.

The memory device 100 may include a stacked body STK. The stacked body STK may include conductive layers CD and interlayer insulating layers IIL that are alternately stacked. The conductive layers CD and the interlayer insulating layers IIL may be alternately stacked in a Z direction (i.e., vertical direction). Each of the conductive layers CD may be formed of at least one of tungsten (W), cobalt (Co), nickel (Ni), molybdenum (Mo), silicon (Si), or polysilicon (Poly-Si). Each of the interlayer insulating layers IIL may be formed of an oxide layer (e.g., silicon oxide layer). The conductive layers CD may correspond to word lines WL (e.g., first to j-th word lines WL1 to WLj of FIG. 2) and a source select line SSL.

The memory device 100 (e.g., first memory block BLK1) may include cell plugs CPL. Each of the cell plugs CP may penetrate the stacked body STK. Each of the cell plugs CPL may extend in the Z direction. The cell plugs CPL may correspond to the strings ST of FIG. 2, respectively. The first to j-th memory cells MC1 to MCj and the source select transistor SST of FIG. 2 may be formed at points where the cell plugs CPL and the conductive layers CD intersect.

Each of the cell plugs CPL may include a blocking layer BX, a charge trap layer CT, a tunnel isolation layer TX, a channel layer CH, a core pillar CO, a capping layer CAP, a spacer SP, and a protective layer PL. The blocking layer BX may have a cylindrical shape. The blocking layer BX may contact the stacked body STK. The charge trap layer CT may be formed along the inner wall of the blocking layer BX. The tunnel isolation layer TX may be formed along the inner wall of the charge trap layer CT. The channel layer CH may be formed along the inner wall of the tunnel isolation layer TX. The core pillar CO may be formed in a cylindrical shape in a region enclosed by the channel layer CH. The capping layer CAP may be coupled to the channel layer CH on the core pillar CO. The capping layer CAP may protrude upward (i.e., Z direction) from the stacked body STK. The spacer SP may enclose the outer side surface of the capping layer CAP on the stacked body STK. For example, the spacer SP may enclose the outer side surface of the capping layer CAP on the stacked body STK in the X and Y directions as shown in FIG. 3. The protective layer PL may cover the top surface of the capping layer CAP.

The blocking layer BX and the tunnel isolation layer TX may be formed of an oxide layer (e.g., silicon oxide layer), an oxynitride layer (e.g., silicon oxynitride layer), or a combination thereof. The charge trap layer CT may include a nitride layer or a variable resistance material. The channel layer CH and the capping layer CAP may be formed of an undoped silicon layer or a doped silicon layer. Because the capping layer CAP and the channel layer CH are made of the same material or a heterogeneous material, a boundary therebetween might not be clearly observed. The core pillar CO may be formed of an insulating layer or a conductive layer. The spacer SP may be formed of an oxide layer (e.g., silicon oxide layer). The protective layer PL may be formed of metal silicide (e.g., TiSi₂).

The channel layer CH included in each of the cell plugs CPL may penetrate the stacked body STK. The channel layer CH may extend in the Z direction. The bottom surface of the channel layer CH may be located at a position lower than or equal to that of the bottom surface of the stacked body STK. The top surface of the channel layer CH may be located at a position equal to that of the top surface of the stacked body STK.

The channel layer CH may have a cylindrical shape. The tunnel isolation layer TX may be disposed on the outer side surface of the channel layer CH. The tunnel isolation layer TX may enclose the outer side surface of the channel layer CH. For example, the tunnel isolation layer TX may enclose the outer side surface of the channel layer CH in the X and Y plane as shown in FIG. 3. Further, the core pillar CO may contact the inner side surface of the channel layer CH. The core pillar CO may be enclosed by the channel layer CH. The core pillar CO may fill at least a portion of a region enclosed by the channel layer CH.

The capping layer CAP may extend upward (i.e., Z direction) from the channel layer CH. The capping layer CAP may contact the inner side surface of the channel layer CH on the core pillar CO. The capping layer CAP may contact the top surface of the core pillar CO. An interface between the capping layer CAP and the core pillar CO may be located lower than that of the top surface of the stacked body STK. Therefore, the core pillar CO might not protrude upward from the stacked body STK. Further, the capping layer CAP may extend into the stacked body STK. In an embodiment, a top surface of the core pillar CO is located lower than the top surface of the stacked body STK as shown in FIG. 3.

The capping layer CAP may protrude upward from the stacked body STK. At least a portion of the capping layer CAP may protrude upward from the top surface of the stacked body STK. For example, the vertical length of the portion of the capping layer CAP protruding further than the stacked body STK may be 160 nm or more. The top surface of the capping layer CAP may be located higher than the top surface of the stacked body STK. Also, the bottom surface of the capping layer CAP may be located lower than the top surface of the stacked body STK. The capping layer CAP may be divided into a first portion P1 and a second portion P2 with respect to the location of the top surface of the stacked body STK. For example, the first portion P1 may be located in the stacked body STK, and the second portion P2 may protrude further than the stacked body STK. The first portion P1 and the second portion P2 of the capping layer CAP are separated for convenience of description, and a boundary therebetween might not be physically identified. In an embodiment, the first portion P1 and the second portion P2 of the capping layer CAP may be one continuous layer.

The first portion P1 of the capping layer CAP may be enclosed by the channel layer CH. The first portion P1 may contact the inner side surface of the channel layer CH and the top surface of the core pillar CO. The first portion P1 may fill a region enclosed by the inner side surface of the channel layer CH and the top surface of the core pillar CO. In an embodiment, the first portion P1 of the capping layer CAP may be enclosed by the channel layer CH, the core pillar CO, and the second portion P2 of the capping layer CAP as shown in FIG. 3. The second portion P2 of the capping layer CAP may be enclosed by the spacer SP. The second portion P2 may fill a region enclosed by the spacer SP. The second portion P2 may contact the inner side surface of the spacer SP and the bottom surface of the protective layer PL. In an embodiment, the second portion P2 of the capping layer CAP may be enclosed by the spacer SP, protective layer PL, and the first portion P1 of the capping layer CAP as shown in FIG. 3.

The spacer SP may have the shape of a cylinder arranged on the stacked body STK. The spacer SP may enclose the capping layer CAP on the stacked body STK. For example, the spacer SP may contact the outer side surface of the second portion P2 of the capping layer CAP. Components other than the capping layer CAP might not be disposed inside the region enclosed by the spacer SP. In an embodiment, the capping layer CAP on the stacked body STK may be enclosed by the spacer SP and the protective layer PL as shown in FIG. 3. In an embodiment, a protective layer PL may cover a top surface of the capping layer CAP as shown in FIG. 3.

The spacer SP may be formed by oxidizing a portion of the channel layer CH and a portion of the capping layer CAP. Therefore, the inner diameter of the plane of the spacer SP may be smaller than the outer diameter of the plane of the channel layer CH. Also, the outer diameter of the plane of the spacer SP may be greater than the outer diameter of the plane of the channel layer CH.

The spacer SP may have a thickness greater than that of the tunnel isolation layer TX. The tunnel isolation layer TX located inside the stacked body STK may have a first thickness WT. The spacer SP disposed on the stacked body STK may have a second thickness WS. The second thickness WS may be greater than the first thickness WT. For example, the second thickness WS may be 200 Å or more.

Further, the spacer SP may have a first height HS. The first height HS may correspond to the height of the second portion P2 of the capping layer CAP. Therefore, the spacer SP may assist in enclosing the side surface of the capping layer CAP so that the capping layer CAP protruding upward from the stacked body STK is not externally exposed.

The memory device 100 may include a liner layer LL extending along the top surface of the stacked body STK and the outer side surface of the spacer SP. The liner layer LL may be conformally formed along the top surface of the stacked body STK and the outer side surface of the spacer SP. The liner layer LL may be formed of a conductive material, for example, molybdenum (Mo).

The liner layer LL may have a second height HL from the top surface of the stacked body STK. The second height HL may be lower than the first height HS. Therefore, the liner layer LL may enclose a portion of the outer side surface of the spacer SP. Another portion of the outer side surface of the spacer SP may be externally exposed on the liner layer LL. For example, a lower portion of the outer side surface of the spacer SP may contact the liner layer LL, and an upper portion of the outer side surface thereof might not contact the liner layer LL. The top surface of the liner layer LL may be located lower than the top surface of the spacer SP.

The liner layers LL may correspond to the first and second drain select lines DSL1 and DSL2 of FIG. 2. The drain select transistors DST of FIG. 2 may be formed at positions where the liner layers LL and capping layers CAP intersect. For example, the capping layers CAP may correspond to the channels of the drain select transistors DST, the spacers SP may correspond to the gate insulating layers of the drain select transistors DST, and the liner layers LL may correspond to the drain select lines DSL1 and DSL2.

The first drain select line DSL1 may be spaced apart from the second drain select line DSL2. For example, the first drain select line DSL1 and the second drain select line DSL2 may be separated from each other by a gap GP between liner layers LL. A portion of the top surface of the stacked body STK may be exposed between the first drain select line DSL1 and the second drain select line DSL2.

The memory device 100 may include an upper insulating layer UIL disposed on the stacked body STK. The upper insulating layer UIL may enclose the liner layers LL, the spacers SP, and the protective layers PL. The upper insulating layer UIL may be disposed between the liner layers LL, that is, between the first drain select line DSL1 and the second drain select line DSL2. Further, the upper insulating layer UIL may be disposed between respective regions extending in the Z direction (e.g., regions enclosing different cell plugs) among the liner layers LL. In an embodiment, the upper insulating layer UIL and stacked body STK may enclose the liner layers LL, the spacers SP, and the protective layers PL.

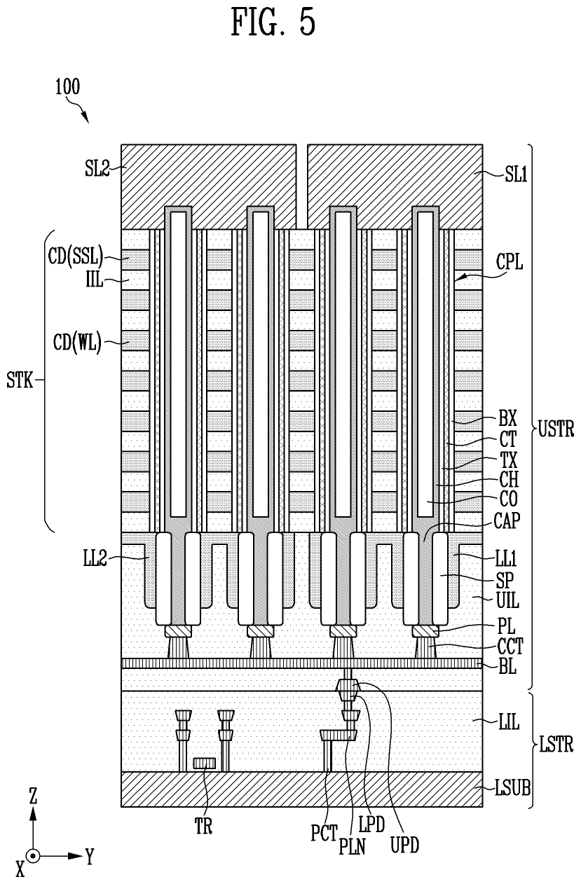

The memory device 100 may include a lower structure SUB under the stacked body STK. In an embodiment, the lower structure SUB may include a substrate. For example, when the memory device 100 is manufactured using a wafer bonding method, the substrate included in the lower structure SUB may be removed later. Details related to the wafer bonding method will be described later with reference to FIG. 5. In an embodiment, the lower structure SUB may include the substrate and a source line (e.g., the source line SL of FIG. 2). When the source line SL is included in the lower structure SUB, the channel layer CH included in each of the cell plugs CPL may directly contact the source line, unlike the illustration of FIG. 3.

According to the present disclosure, in an embodiment, the drain select transistors DST included in the memory device 100 may function as high voltage transistors. In an embodiment, as the second thickness WS of the spacers SP increases, the breakdown voltage of the drain select transistors DST may increase. For example, when the second thickness WS of the spacers SP is 200 Å or more, the breakdown voltage of the drain select transistors DST may be 15 V or more. Therefore, in an embodiment, because the spacers SP having the second thickness WS larger than the first thickness WT are used as gate insulating layers of the drain select transistors DST, the drain select transistors DST may function as the high voltage transistors. Further, in an embodiment, because each spacer SP is formed by oxidizing the channel layer CH and the capping layer CAP, for example, pure polysilicon, the drain select transistors DST may secure a stable gate voltage.

Furthermore, according to an embodiment of the present disclosure, each drain select transistor DST may have a gate all around (GAA) structure in which the liner layer LL encloses the spacer SP. According to an embodiment of the present disclosure, because the charge trap layer CT is not formed around the capping layer CAP and the spacer SP directly contacts the capping layer CAP, a sufficient space for separating the drain select lines DSL1 and DSL2 may be secured. Therefore, the memory device 100 according to an embodiment of the present disclosure might not include a dummy cell plug. For an embodiment, in the case where the memory device 100 includes only drain select transistors DST having a GAA structure, a drop or leakage of current applied to the memory cells MC may be prevented or mitigated compared to the case where the memory device includes dummy cell plugs.

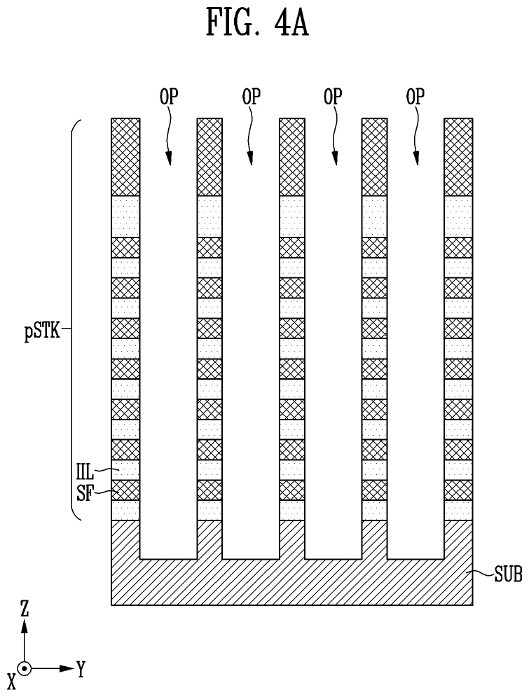

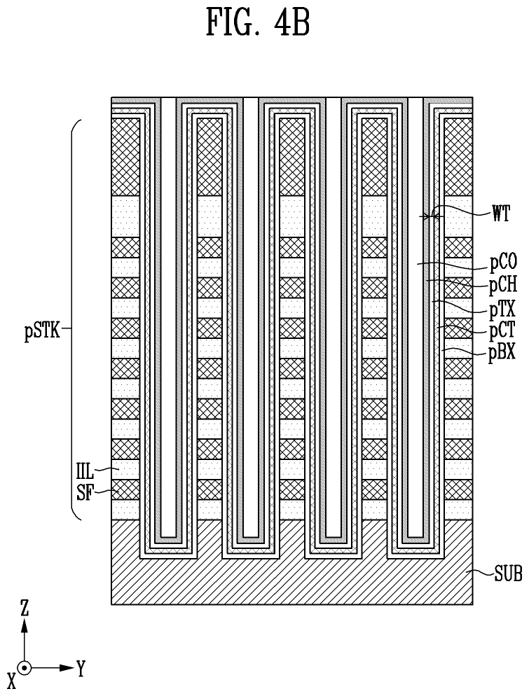

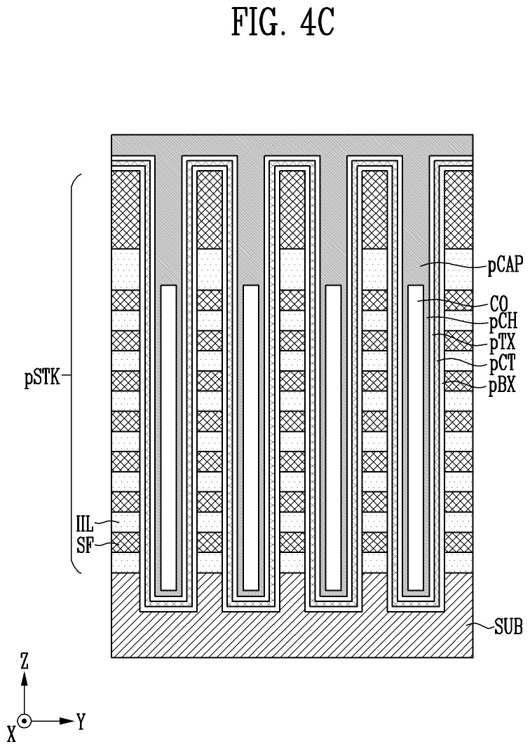

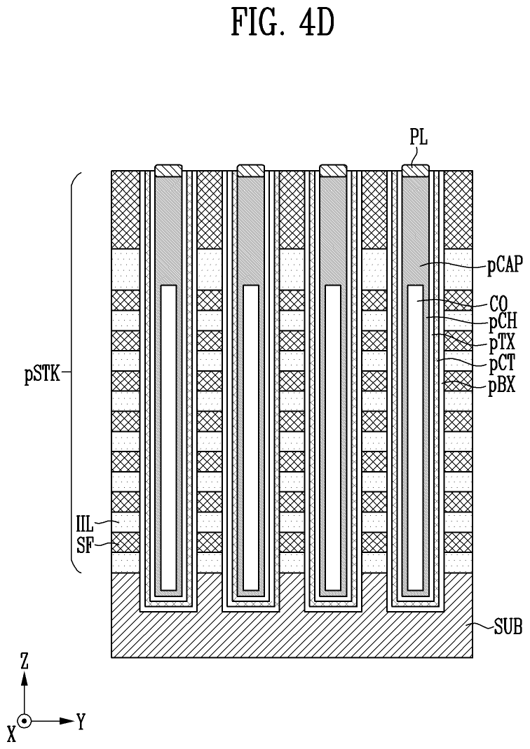

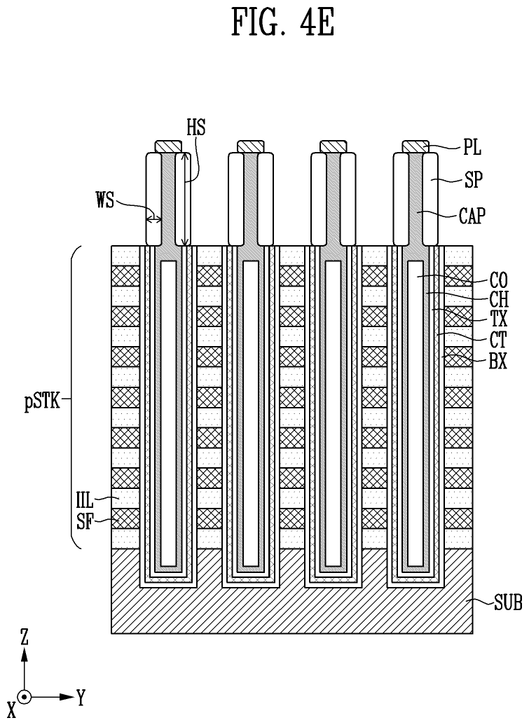

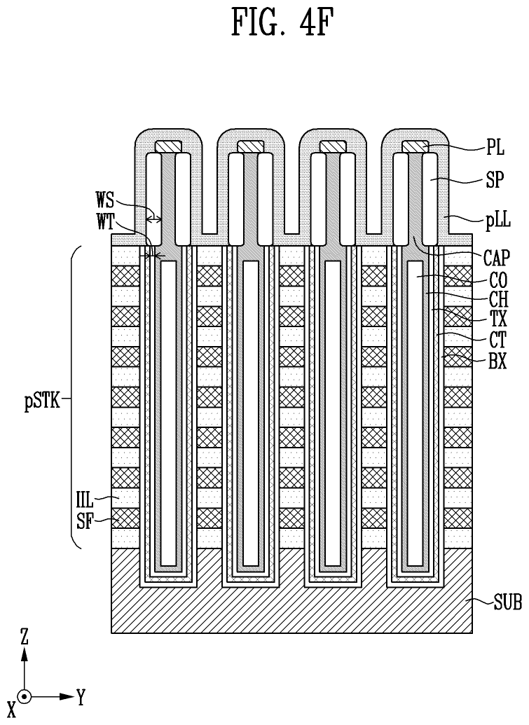

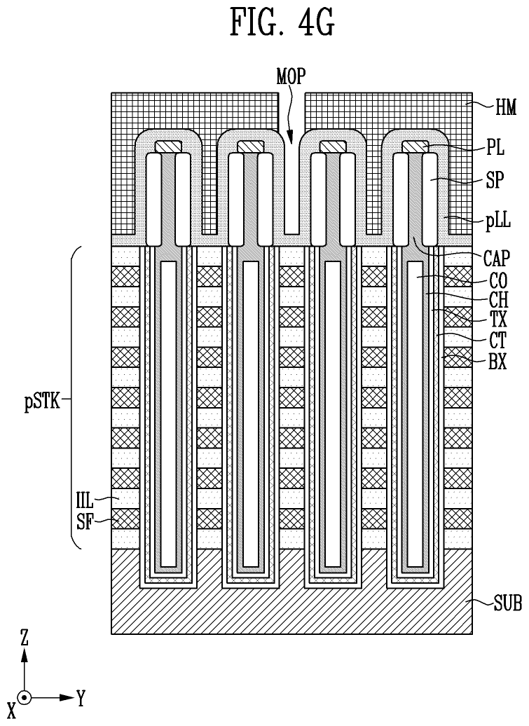

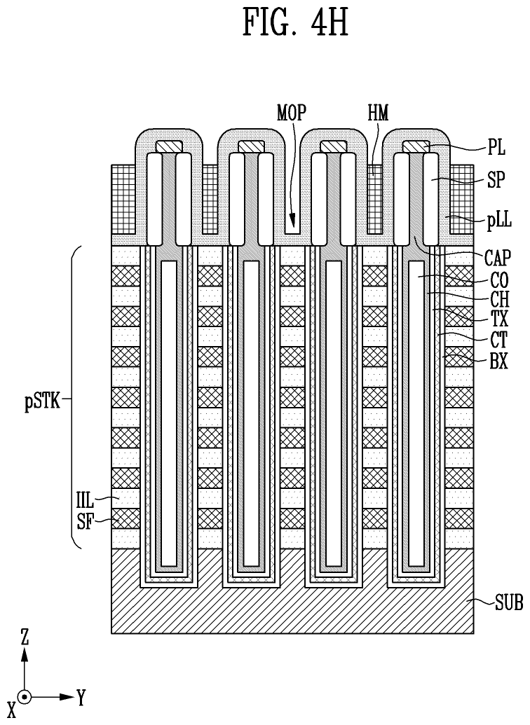

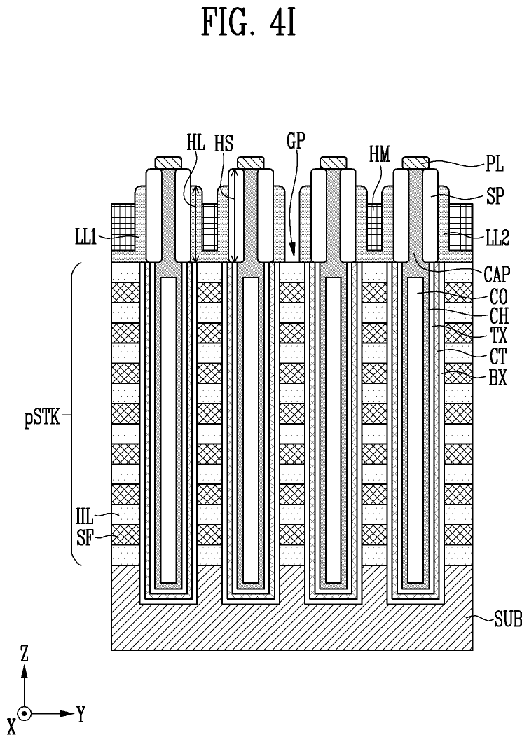

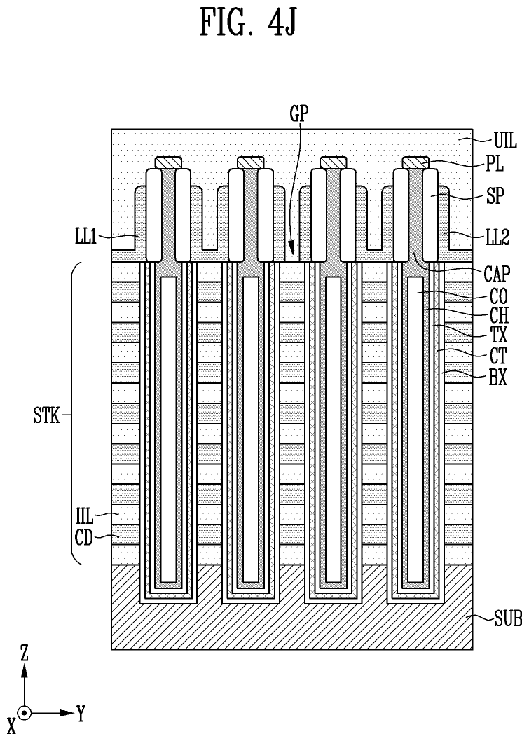

FIGS. 4A to 4J are views illustrating a method of manufacturing a memory device according to an embodiment of the present disclosure.

Referring to FIG. 4A, a preliminary stacked body pSTK may be formed on a lower structure SUB. The preliminary stacked body pSTK may include first material layers IIL and second material layers SF that are alternately stacked along a Z direction. Each of the first material layers IIL may be formed of an insulating material. For example, each of the first material layers IIL may be formed of an oxide layer (e.g., silicon oxide layer). The second material layers SF may be formed of a material that can be selectively removed in a subsequent process. Therefore, the second material layers SF may be formed of a material having an etch selectivity different from that of the first material layers IIL. For example, each of the second material layers SF may be formed of a nitride layer.

The thicknesses of the first and second material layers IIL and SF included in the preliminary stacked body pSTK may vary depending on the position. For example, a first material layer IIL having a second thickness larger than a first thickness and a second material layer SF having a third thickness larger than the second thickness may be formed on the first and second material layers IIL and SF, each having a uniform thickness (e.g., first thickness). For example, the third thickness of the second material layer SF disposed in an uppermost portion may be 2000 Å.

Further, openings OP passing through the preliminary stacked body pSTK may be formed. The openings OP may pass through the first and second material layers IIL and SF of the preliminary stacked body pSTK. The openings OP may be arranged along an X direction and a Y direction. Each of the openings OP may extend in a Z direction. Each of the openings OP may have a hole shape. A lower portion of each of the openings OP may be located inside the lower structure SUB.

Referring to FIG. 4B, a preliminary blocking layer pBX, a preliminary charge trap layer pCT, a preliminary tunnel isolation layer pTX, a preliminary channel layer pCH, and a preliminary core pillar pCO may be formed on the preliminary stacked body pSTK. For example, the preliminary blocking layer pBX, the preliminary charge trap layer pCT, the preliminary tunnel isolation layer pTX, the preliminary channel layer pCH, and the preliminary core pillar pCO may be sequentially formed along the top surface of the preliminary stacked body pSTK and the inner side surfaces of the openings OP. The preliminary blocking layer pBX, the preliminary charge trap layer pCT, the preliminary tunnel isolation layer pTX, the preliminary channel layer pCH, and the preliminary core pillar pCO may be deposited in each of the openings OP.

Each of the preliminary blocking layer pBX, the preliminary charge trap layer pCT, the preliminary tunnel isolation layer pTX, the preliminary channel layer pCH, and the preliminary core pillar pCO may penetrate the preliminary stacked body pSTK. For example, the preliminary channel layer pCH may penetrate the preliminary stacked body pSTK. Also, the preliminary tunnel isolation layer pTX may enclose the outer side surface of the preliminary channel layer pCH. The preliminary tunnel isolation layer pTX may have a first thickness WT. The preliminary core pillar pCO may be enclosed by the preliminary channel layer pCH. The preliminary core pillar pCO may fill a space enclosed by the preliminary channel layer pCH. The top surface of the preliminary core pillar pCO may be located at the same height as the top surface of the preliminary channel layer pCH.

Referring to FIG. 4C, a portion of the preliminary core pillar pCO may be removed, and thus a core pillar CO may be formed. A portion of the preliminary core pillar pCO may be etched, and then a recess may be formed. For example, the portion of the preliminary core pillar pCO may be etched to correspond to the height of a second material layer SF that is second from the top, among the second material layers SF included in the preliminary stacked body pSTK. As the portion of the preliminary core pillar pCO is removed, a portion of the preliminary channel layer pCH may be exposed. For example, a portion of the inner side surface of the preliminary channel layer pCH may be exposed. In order to selectively etch the preliminary core pillar pCO, an isotropic wet etching process may be performed.

After the portion of the preliminary core pillar pCO is removed, a preliminary capping layer pCAP may be formed. The preliminary capping layer pCAP may fill a region from which the preliminary core pillar pCO is removed. The preliminary capping layer pCAP may contact the top of the preliminary channel layer pCH. For example, the preliminary capping layer pCAP may contact the exposed inner side surface and the top surface of the preliminary channel layer pCH. Further, the preliminary capping layer pCAP may contact the top surface of the core pillar CO. In FIG. 4C and subsequent drawings, an illustration of an interface between the preliminary channel layer pCH and the preliminary capping layer pCAP may be omitted.

After the preliminary capping layer pCAP is formed, a laser annealing process may be performed. Through the laser annealing process, the preliminary channel layer pCH and the preliminary capping layer pCAP may be crystallized. For example, when the laser annealing process is performed on the preliminary channel layer pCH and the preliminary capping layer pCAP, each containing polysilicon, the preliminary channel layer pCH and the preliminary capping layer pCAP may contain single crystal silicon.

Referring to FIG. 4D, portions of the preliminary capping layer pCAP and the preliminary channel layer pCH which are disposed on the top surface of the preliminary stacked body pSTK may be removed. Furthermore, portions of the preliminary blocking layer pBX, the preliminary charge trap layer pCT, and the preliminary tunnel isolation layer pTX which are disposed on the top surface of the preliminary stacked body pSTK may be removed. Therefore, the top surface of the preliminary stacked body pSTK may be exposed. As the top surface of the preliminary stacked body pSTK is exposed, preliminary capping layers pCAP and preliminary channel layers pCH may be respectively separated and disposed in respective openings OP.

Protective layers PL covering the top surfaces of the preliminary capping layers pCAP and the preliminary channel layers pCH may be formed. For example, when annealing is performed after a metal layer is deposited on each preliminary channel layer pCH and each preliminary capping layer pCAP, metal silicide may be formed. Each of the protective layers PL may be made of TiSi₂, CoSi₂, or NiSi. The protective layers PL may cover the top surfaces of the preliminary capping layers pCAP and the top surfaces of the preliminary channel layers pCH.

During a subsequent process, in an embodiment, the protective layers PL may prevent or mitigate the preliminary channel layers pCH and the preliminary capping layers pCAP from being lost. Also, in an embodiment, the protective layers PL may decrease resistivity of a path for coupling cell plugs CPL to bit lines BL.

Referring to FIG. 4E, a portion of the preliminary stacked body pSTK may be removed. For example, among the second material layers SF included in the preliminary stacked body pSTK, the second material layer SF in the uppermost portion may be removed. Further, among the first material layers IIL included in the preliminary stacked body pSTK, a portion of the first material layer IIL in the uppermost portion may be removed. The top surface of the preliminary stacked body pSTK, the portion of which is removed, may be located higher than the top surface of the core pillar CO. In an embodiment, the top surface of the preliminary stacked body pSTK, the portion of which is removed, may be located higher than the top surface of the core pillar CO as shown in FIG. 4E.

Further, portions of the preliminary blocking layer pBX, the preliminary charge trap layer pCT, and the preliminary tunnel isolation layer pTX may be removed. Portions of the preliminary blocking layer pBX, the preliminary charge trap layer pCT, and the preliminary tunnel isolation layer pTX, which are exposed as the upper portion of the preliminary stacked body pSTK is removed, may be removed. The preliminary blocking layer pBX, the preliminary charge trap layer pCT, and the preliminary tunnel isolation layer pTX, which remain after respective upper portions thereof are removed, may correspond to a blocking layer BX, a charge trap layer CT, and a tunnel isolation layer TX, respectively. Furthermore, as the upper portions of the preliminary blocking layer pBX, the preliminary charge trap layer pCT, and the preliminary tunnel isolation layer pTX are removed, a portion of the preliminary channel layer pCH may be exposed. For example, an upper portion of the outer side surface of the preliminary channel layer pCH may be exposed.

A spacer SP may be formed by oxidizing the preliminary channel layer pCH and the preliminary capping layer pCAP. A region of the preliminary channel layer pCH, which is externally exposed, may be oxidized. For example, the entire portion of the preliminary channel layer pCH, which is located above the top surface of the preliminary stacked body pSTK, may be oxidized. Furthermore, a portion of the preliminary capping layer pCAP, enclosed by the oxidized preliminary channel layer pCH, may be oxidized. For example, a portion of the preliminary capping layer pCAP, which is located above the top surface of the preliminary stacked body pSTK, may be oxidized. Oxidization may sequentially occur in such a way that a region adjacent to the preliminary channel layer pCH among regions of the preliminary capping layer pCAP is first oxidized. A portion of the preliminary channel layer pCH, which is not oxidized, may correspond to a channel layer CH. A portion of the preliminary capping layer pCAP, which is not oxidized, may correspond to a capping layer CAP.

Because the spacer SP is formed by oxidizing externally exposed regions, among the regions of the preliminary channel layer pCH and the preliminary capping layer pCAP, the spacer SP may have the shape of a cylinder enclosing the capping layer CAP. The spacer SP may enclose the side surface of the capping layer CAP.

The spacer SP may have a second thickness WS. The second thickness WS may be greater than the first thickness WT of the tunnel isolation layer TX. For example, the spacer SP having a thickness of 200 Å may be formed by oxidizing the preliminary channel layer pCH having a thickness of 70 Å and the preliminary capping layer pCAP having a thickness of 50 Å.

The spacer SP may have a first height HS. The first height HS may correspond to the height of a portion of the capping layer CAP protruding from the top surface of the preliminary stacked body pSTK. In FIG. 4E, the height of the removed upper portion of the preliminary stacked body pSTK may correspond to the first height HS. For example, the first height HS and the height of the capping layer CAP used as the channel of the drain select transistor DST may be 160 nm or more. Alternatively, the first height HS may be higher than the height of the portion of the capping layer CAP protruding from the top surface of the preliminary stacked body pSTK.

Referring to FIG. 4F, a preliminary liner layer pLL may be formed on the preliminary stacked body pSTK. The preliminary liner layer pLL may cover the top surface of the preliminary stacked body pSTK, the spacers SP, and the protective layers PL. The preliminary liner layer pLL may extend along the top surface of the preliminary stacked body pSTK, the spacers SP, and the protective layers PL. The preliminary liner layer pLL may be conformally deposited on the top surface of the preliminary stacked body pSTK, the spacers SP, and the protective layers PL. For example, the preliminary liner layer pLL may contain a material having good step coverage, for example, molybdenum (Mo).

According to the present disclosure, because the drain select transistor DST includes only the spacer SP, but does not include the blocking layer BX, the charge trap layer CT, and the tunnel isolation layer TX, a gap between spacers SP may be sufficiently wide. For example, the distance between the spacers SP included in different cell plugs may be longer than the distance between the blocking layers BX included in different cell plugs. Therefore, a sufficient space in which the preliminary liner layer pLL extending in the Z direction can be formed may be secured on the side surfaces of the spacers SP.

Referring to FIG. 4G, a hard mask HM may be formed on the preliminary stacked body pSTK. The hard mask HM may cover the preliminary liner layer pLL.

A portion of the hard mask HM may be removed, and then a mask opening MOP may be formed. The mask opening MOP may correspond to some of regions disposed between the spacers SP. For example, the mask opening MOP may correspond to a position at which the gap GP is to be formed in FIG. 3.

Referring to FIG. 4H, an upper portion of the hard mask HM may be removed. As a portion of the hard mask HM is etched, the hard mask HM may be disposed in some of regions disposed between the spacers SP, and might not be disposed in other regions. For example, the hard mask HM might not remain in a region corresponding to the mask opening MOP, among the regions disposed between the spacers SP. Further, the hard mask HM may remain in a region that does not correspond to the mask opening MOP, among the regions disposed between the spacers SP.

Referring to FIG. 4I, a portion of the preliminary liner layer pLL may be removed, and then first and second liner layers LL1 and LL2 may be formed. In order to etch the preliminary liner layer pLL, the hard mask HM may be used as an etching barrier. Therefore, in the region corresponding to the mask opening MOP, the preliminary liner layer pLL may be removed, and then a gap GP may be formed. Further, in the region in which the hard mask HM remains, the preliminary liner layer pLL might not be removed. A process of etching the preliminary liner layer pLL using the scheme described in FIGS. 4G to 4I may be referred to as a self-align etching process.

The first and second liner layers LL1 and LL2 may respectively correspond to the first and second drain select lines DSL1 and DSL2 of FIG. 2. The first and second liner layers LL1 and LL2 may be spaced apart from each other in a Y direction. The first and second liner layers LL1 and LL2 may be insulated from each other by the gap. A portion of the top surface of the preliminary stacked body pSTK may be exposed between the first and second liner layers LL1 and LL2.

According to an embodiment of the present disclosure, the space between the spacers SP is sufficiently large, thus making it easy to insulate the first and second drain select lines DSL1 and DSL2 from each other. For example, because the preliminary liner layer pLL may be separated into the first and second liner layers LL1 and LL2 insulated from each other by removing a portion of the preliminary liner layer pLL, the memory device 100 might not include dummy cell plugs.

Further, while the preliminary liner layer pLL is etched, the height of the preliminary liner layer pLL may be decreased. Therefore, the first and second liner layers LL1 and LL2, the heights of which become lower than that of the preliminary liner layer pLL, may be formed. Each of the first and second liner layers LL1 and LL2 may have a second height HL. The second height HL may be lower than the first height HS of each spacer SP. The first and second liner layers LL1 and LL2 may extend along the top surface of the preliminary stacked body pSTK and the outer side surface of each spacer SP. The first and second liner layers LL1 and LL2 may expose portions (e.g., upper portions) of the outer side surfaces of the spacers SP. The first and second liner layers LL1 and LL2 might not cover the protective layers PL.

Referring to FIG. 4J, the hard mask HM remaining on the first and second liner layers LL1 and LL2 may be removed. Further, an upper insulating layer UIL may be formed on the preliminary stacked body pSTK. Furthermore, the second material layers SF may be replaced with third material layers CD, and then a stacked body STK may be formed. Each of the third material layers CD may be formed of a conductive material.

FIG. 5 is a diagram illustrating an example of a source line included in a memory device according to an embodiment of the present disclosure.

Referring to FIG. 5, the memory device 100 may include a lower structure LSTR and an upper structure USTR stacked on the lower structure LSTR. The upper structure USTR may include the stacked body STK and the cell plugs CPL, which are illustrated in FIG. 3. For example, it may be understood that the structure illustrated in FIG. 3 is upside down, and the upside-down structure is stacked on the lower structure LSTR.

The lower structure LSTR may include a lower substrate LSUB and a peripheral circuit (e.g., peripheral circuit 170 of FIG. 1) on the lower substrate LSUB. For example, the peripheral circuit may include a transistor TR, a peripheral contact plug PCT, and a peripheral line PLN. The transistor TR, the peripheral contact plug PCT, and the peripheral line PLN may have various patterns depending on the peripheral circuit. For example, the numbers or arrangement positions of transistors TR, peripheral contact plugs PCT, and peripheral lines PLN may be modified in various forms. A lower insulating layer LIL may be disposed between the transistor TR, the peripheral contact plug PCT, and the peripheral line PLN. For example, the transistor TR, the peripheral contact plug PCT, and the peripheral line PLN may be formed in the lower insulating layer LIL.

The lower structure LSTR may include a lower pad LPD exposed to the top surface of the lower structure LSTR. Further, the upper structure USTR may include an upper pad UPD exposed to the bottom surface of the upper structure USTR. When the upper structure USTR is stacked on the lower structure LSTR, the upper pad UPD may contact the lower pad LPD. Each of the upper pad UPD and the lower pad LPD may contain a conductive material.

The upper structure USTR may include a bit line BL and cell contacts CCT. The bit line BL and the cell contacts CCT may be disposed below the stacked body STK. The bit line BL and the cell contacts CCT may be formed in the upper insulating layer UIL. The bit line BL may be coupled to the cell plugs CPL through the cell contacts CCT. The cell contacts CCT may contact protective layers PL of the cell plugs CPL. Furthermore, the bit line BL may be coupled to the peripheral circuit (e.g., the peripheral circuit 170 of FIG. 1) through the upper pad UPD and the lower pad LPD.

The upper structure USTR may include a source line (e.g., the source line SL of FIG. 2) disposed on the stacked body STK. In an embodiment, the upper structure USTR may include first and second sub-source lines SL1 and SL2 disposed on the stacked body STK. The first sub-source line SL1 and the second sub-source line SL2 may be spaced apart from each other in a Y direction. For example, the cell plugs CPL coupled to the first liner layer LL1 may be coupled to the first sub-source line SL1, and the cell plugs CPL coupled to the second liner layer LL2 may be coupled to the second sub-source line SL2.

That is, in an embodiment, the memory device 100 may be operated in units of a sub-block which is a unit smaller than a memory block (e.g., first to i-th memory blocks BLK1 to BLKi of FIG. 1) through source line cutting. For example, the memory device 100 may perform an erase operation on a sub-block basis. Because the memory device 100 according to an embodiment of the present disclosure includes the drain select transistors DST operable as high voltage transistors, the memory device 100 may be operated on a sub-block basis.

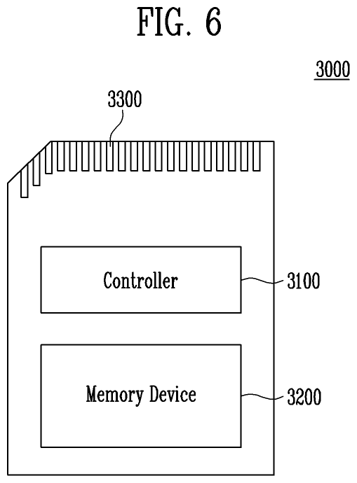

FIG. 6 is a diagram illustrating a memory card system to which a memory device according to an embodiment of the present disclosure is applied.

Referring to FIG. 6, a memory card system 3000 may include a controller 3100, a memory device 3200, and a connector 3300.

The controller 3100 may be coupled to the memory device 3200. The controller 3100 may access the memory device 3200. For example, the controller 3100 may control a program operation, a read operation, or an erase operation of the memory device 3200, or may control a background operation of the memory device 3200. The controller 3100 may provide an interface between the memory device 3200 and a host. The controller 3100 may run firmware for controlling the memory device 3200. In an example, the controller 3100 may include components, such as a random access memory (RAM), a processor, a host interface, a memory interface, and an error corrector.

The controller 3100 may communicate with an external device through the connector 3300. The controller 3100 may communicate with an external device (e.g., a host) based on a specific communication standard. For example, the controller 3100 may communicate with the external device through at least one of various communication standards such as universal serial bus (USB), multimedia card (MMC), embedded MMC (eMMC), peripheral component interconnection (PCI), PCI-express (PCI-E), advanced technology attachment (ATA) protocol, serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). For example, the connector 3300 may be defined by at least one of the above-described various communication standards.

The memory device 3200 may include a plurality of memory cells, and may be configured in the same manner as the memory device 100 illustrated in FIG. 1.

The controller 3100 and the memory device 3200 may be integrated into a single semiconductor device to form a memory card. For example, the controller 3100 and the memory device 3200 may be integrated into a single semiconductor device, and may then form a memory card such as a personal computer memory card international association (PCMCIA) card, a compact flash card (CF), a smart media card (SM or SMC), a memory stick, a multimedia card (MMC, RS-MMC, MMCmicro or eMMC), an SD card (SD, miniSD, microSD, or SDHC), or a universal flash storage (UFS).

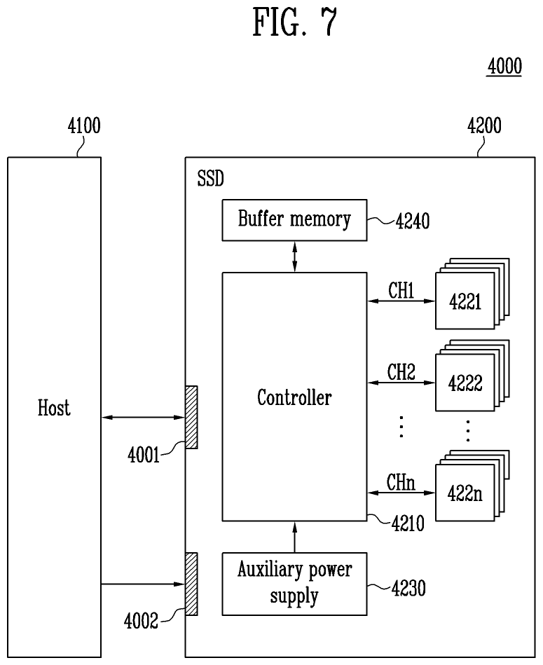

FIG. 7 is a diagram illustrating a solid state drive (SSD) system to which a memory device according to the present disclosure is applied.

Referring to FIG. 7, an SSD system 4000 may include a host 4100 and an SSD 4200. The SSD 4200 may exchange signals with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. For example, the received signals may be signals based on the interfaces of the host 4100 and the SSD 4200. For example, the signals may be defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n may include a plurality of memory cells configured to store data. Each of the memory devices 4221 to 422n may be configured in the same manner as the memory device 100 illustrated in FIG. 1. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied with a supply voltage from the host 4100, and may be charged. The auxiliary power supply 4230 may provide the supply voltage of the SSD 4200 when the supply of power from the host 4100 is not smoothly performed. For example, the auxiliary power supply 4230 may be located inside the SSD 4200 or located outside the SSD 4200. For example, the auxiliary power supply 4230 may be located in a main board, and may provide auxiliary power to the SSD 4200.

The buffer memory 4240 may function as a buffer memory of the SSD 4200. For example, the buffer memory 4240 may store, for a limited duration, data received from the host 4100 or data received from the plurality of memory devices 4221 to 422n, or may store, for a limited duration, metadata (e.g., mapping tables) of the memory devices 4221 to 422n. The buffer memory 4240 may include volatile memories, such as a dynamic random access memory (DRAM), a synchronous DRAM (SDRAM), a double data rate (DDR) SDRAM, and a low power DDR (LPDDR) SDRAM, or nonvolatile memories, such as a ferroelectric RAM (FRAM), a resistive RAM (ReRAM), a spin transfer torque magnetic RAM (STT-MRAM), and a phase-change RAM (PRAM).

An embodiment of, the present disclosure may enhance the performance of a select transistor by improving the structure of the select transistor.

What is claimed is:

1. A memory device, comprising:
a stacked body including interlayer insulating layers and conductive layers alternately stacked with one another in a first direction;
a channel layer penetrating the stacked body;
a tunnel isolation layer enclosing an outer side surface of the channel layer and having a first thickness;
a capping layer extending from the channel layer and protruding from the stacked body in the first direction;
a spacer enclosing an outer side surface of the capping layer on the stacked body and having a second thickness greater than the first thickness; and
a liner layer extending along a top surface of the stacked body and at least a portion of an outer side surface of the spacer.

2. The memory device according to claim 1, wherein:
the capping layer comprises a first portion located inside the stacked body and a second portion protruding from the stacked body in the first direction,
the first portion is enclosed by the channel layer, and
the second portion is enclosed by the spacer.

3. The memory device according to claim 2, further comprising:
a core pillar disposed under the first portion and enclosed by the channel layer.

4. The memory device according to claim 3, wherein a top surface of the core pillar is located lower than the top surface of the stacked body.

5. The memory device according to claim 1, further comprising:
a protective layer covering a top surface of the capping layer.

6. The memory device according to claim 1, wherein:
the spacer has a first height in the first direction, and
the liner layer has a second height in the first direction lower than the first height in the first direction.

7. The memory device according to claim 1, wherein:
the liner layer encloses a portion of the outer side surface of the spacer, and
another portion of the outer side surface of the spacer is externally exposed by the liner layer.

8. The memory device according to claim 1, wherein:
the liner layer is a drain select line, and
each of the conductive layers is a word line or a source select line.

9. The memory device according to claim 1, wherein:
the channel layer, the tunnel isolation layer, the capping layer, and the spacer are included in a first cell plug,
the liner layer is a first drain select line, and
the memory device further comprises a second cell plug spaced apart from the first cell plug in a second direction of the first cell plug, and a second drain select line spaced apart from the first drain select line in the second direction of the first drain select line.

10. The memory device according to claim 9, wherein the first drain select line and the second drain select line are separated from each other.

11. The memory device according to claim 9, wherein a portion of the top surface of the stacked body is exposed between the first drain select line and the second drain select line.

12. The memory device according to claim 9, further comprising:
a source line disposed under the stacked body.

13. The memory device according to claim 12, wherein the source line comprises:
a first sub-source line coupled to the first cell plug; and
a second sub-source line coupled to the second cell plug.

14. A method of manufacturing a memory device, comprising:
forming a preliminary channel layer penetrating a stacked body, and a tunnel isolation layer enclosing an outer side surface of the preliminary channel layer, wherein the tunnel isolation layer has a first thickness;
forming a preliminary capping layer contacting a top of the preliminary channel layer;
exposing a portion of the preliminary channel layer by removing an upper portion of the stacked body;
forming a spacer having a second thickness greater than the first thickness by oxidizing the exposed preliminary channel layer and the preliminary capping layer; and
forming a liner layer extending along a top surface of the stacked body and the spacer.

15. The method according to claim 14, wherein forming the preliminary channel layer and the tunnel isolation layer comprises:
forming a core pillar enclosed by the preliminary channel layer.

16. The method according to claim 15, wherein forming the preliminary capping layer comprises:
removing a portion of the core pillar; and
filling a region in which the core pillar is removed with the preliminary capping layer.

17. The method according to claim 14, further comprising, after forming the preliminary capping layer:
forming a protective layer on a top surface of the preliminary capping layer.

18. The method according to claim 17, wherein forming the liner layer comprises:
forming a preliminary liner layer on the top surface of the stacked body, the spacer, and the protective layer; and
forming the liner layer having a height lower than a height of the spacer by removing a portion of the preliminary liner layer.

19. The method according to claim 18, wherein forming the liner layer comprises:
exposing a portion of the top surface of the stacked body by removing a portion of the preliminary liner layer.
